(19) United States
(12) Patent Application Publication
(10) Pub. No.: US 2012/0261560 A1
(43) Pub. Date: Oct. 18, 2012

(54) LIGHT GUIDE, ILLUMINATION APPARATUS, AND ELECTRONIC APPARATUS

(75) Inventors: Koya Nomoto, Saitama (JP); Kazuhito Kunishima, Saitama (JP); Masayoshi Kawata, Saitama (JP)

(73) Assignee: SONY CORPORATION, Tokyo (JP)

(21) Appl. No.: 13/436,292

(22) Filed: Mar. 30, 2012

(30) Foreign Application Priority Data
Apr. 12, 2011 (JP) 2011-088110

(51) Int. Cl. H01L 31/12; G02B 6/10; G02B 6/00

(52) U.S. Cl. 250/227.32; 362/551; 385/146

(57) ABSTRACT

A light guide including: a body light guide portion including an incident end that light from a light source enters; and a branch light guide portion including a first light guide portion and a second light guide portion that each include an emission end that a light flux exits and are branched from the body light guide portion, the branch light guide portion being configured to cause, such that a first light flux emitted from the first light guide portion directly heads toward an irradiation object and a second light flux emitted from the second light guide portion heads toward the irradiation object via a reflection portion and joins the first light flux, the first light flux and the second light flux to be emitted from the emission ends.

### CROSS REFERENCES TO RELATED APPLICATIONS

The present application claims priority to Japanese Priority Patent Application JP 2011-088110 filed in the Japan Patent Office on Apr. 12, 2011, the entire content of which is hereby incorporated by reference.

### BACKGROUND

The present disclosure relates to a light guide that guides light from a light source and causes it to be emitted linearly, and an illumination apparatus and electronic apparatus that use the light guide.

From the past, in scanners and complex machines, there has been a light guide that has a special shape for uniformly irradiating light onto an irradiation object (see, for example, Japanese Patent Application Laid-open No. 2008-123766).

In a lighting device disclosed in Japanese Patent Application Laid-open No. 2000-101788 (hereinafter, referred to as Patent Document 2), light emitted from one light source enters a light guide member, and the light guide member mainly emits two light fluxes such that the light fluxes join at a lighting position. As a result, generation of shadows due to a paste-up script can be suppressed (see, for example, paragraph [0014] of Patent Document 2).

### SUMMARY

Hereafter, a technique with which light can be uniformly irradiated onto an irradiation object for suppressing generation of shadows in the irradiation object as in the lighting device of Patent Document 2 may be required.

In view of the circumstances as described above, there is a need for a light guide, an illumination apparatus, and an electronic apparatus that are capable of uniformly irradiating light onto an irradiation object.

According to an embodiment of the present disclosure, there is provided a light guide including a body light guide portion and a branch light guide portion.

The body light guide portion includes an incident end that light from a light source enters.

The branch light guide portion includes a first light guide portion and a second light guide portion that each include an emission end that a light flux exits and are branched from the body light guide portion, the branch light guide portion being configured to cause, such that a first light flux emitted from the first light guide portion directly heads toward an irradiation object and a second light flux emitted from the second light guide portion heads toward the irradiation object via a reflection portion and joins the first light flux, the first light flux and the second light flux to be emitted from the emission ends.

Since the first light guide portion and the second light guide portion are branched from the body light guide portion and the first light flux and the second light flux emitted therefrom join, light can be uniformly irradiated onto the irradiation object.

The body light guide portion may be formed such that a volume thereof increases from the incident end side toward the branch light guide portion side. With this structure, directivity of light that passes the body light guide portion can be enhanced, and the light fluxes that enter from the light source to be diffused can be efficiently guided to the branch light guide portion.

At least one of the first light guide portion and the second light guide portion may be formed such that a volume thereof increases from the body light guide portion side toward the emission end side. With this structure, directivity of light that exits via at least one of the first light guide portion and the second light guide portion can be enhanced, and the light fluxes diffused from the body light guide portion side can be guided efficiently.

The emission end of at least one of the first light guide portion and the second light guide portion may be formed in a light-collecting shape. With this structure, well-shaped accurately-linear light can be irradiated onto the irradiation object

The light guide may be split from the incident end of the body light guide portion to a branching portion of the first light guide portion and the second light guide portion in the branch light guide portion. With this structure, a light guide can be formed by attaching another split light guide.

According to an embodiment of the present disclosure, there is provided an illumination apparatus including a light source, a reflection portion, and the light guide described above.

The illumination apparatus may further include a light diffusion member provided between the light source and the incident end of the light guide. With this structure, illuminance unevenness can be suppressed.

According to an embodiment of the present disclosure, there is provided an electronic apparatus including the illumination apparatus described above and a photoelectric conversion portion. The photoelectric conversion portion is configured to receive the light fluxes from the light guide that have been reflected by the irradiation object and convert the light fluxes into an electric signal.

As described above, according to the embodiments of the present disclosure, light can be uniformly irradiated onto an irradiation object.

Additional features and advantages are described herein, and will be apparent from the following Detailed Description and the figures.

### BRIEF DESCRIPTION OF THE FIGURES

FIG. 1 is a diagram showing a structure of an illumination apparatus according to a first embodiment of the present disclosure;

FIG. 2 is a cross-sectional diagram showing a light guide;

FIG. 3A is a diagram simulating generation of light fluxes by the illumination apparatus, and FIG. 3B is a diagram simulating generation of light fluxes by an illumination apparatus according to another embodiment of the present disclosure;

FIG. 4A is a diagram showing one light beam in a light guide that is formed such that a volume thereof increases from an incident end side to an emission end side, and FIG. 4B is a diagram showing one light beam in a light guide that is formed such that a volume thereof is practically constant from the incident end side to the emission end side;

FIG. 5 is a diagram showing a more-specific embodiment of the illumination apparatus according to the first embodiment;

FIG. 6 is a cross-sectional diagram of a light guide according to a second embodiment of the present disclosure; and

FIG. 7 is a cross-sectional diagram showing an illumination apparatus according to a third embodiment of the present disclosure.

### DETAILED DESCRIPTION

Hereinafter, embodiments of the present disclosure will be described with reference to the drawings.

### First Embodiment

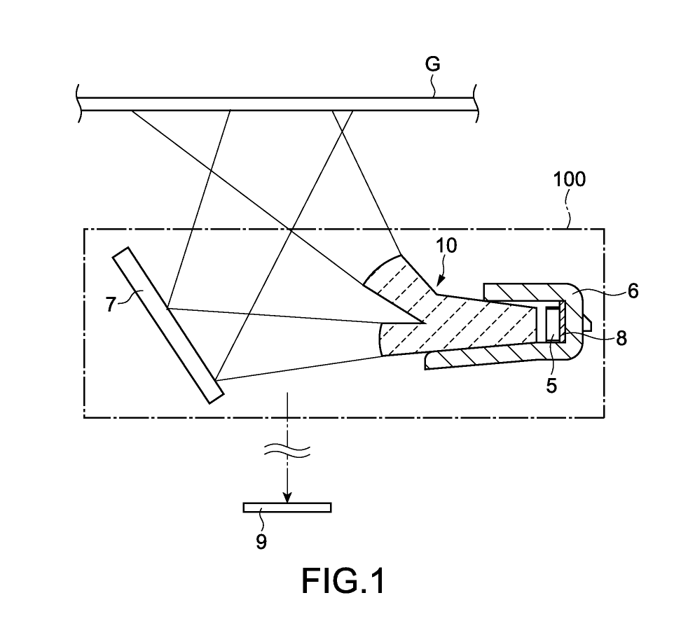

FIG. 1 is a diagram showing a structure of an illumination apparatus according to a first embodiment of the present disclosure.

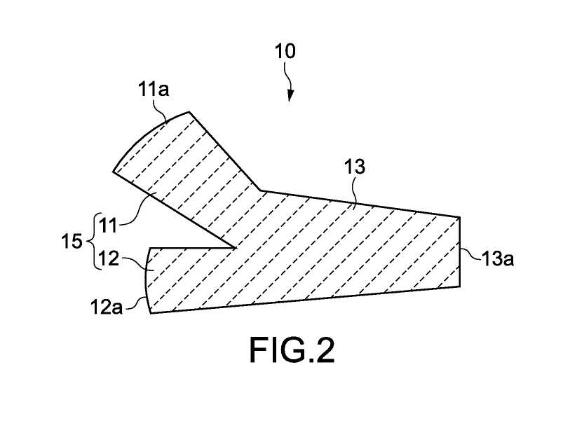

The illumination apparatus 100 is used in an electronic apparatus such as a scanner and a so-called complex machine. A complex machine is an apparatus including both functions as a printer and a copying machine. The illumination apparatus 100 includes a light source 5, a light guide 10, and a reflection portion 7 and opposes an irradiation object G. FIG. 2 is a cross-sectional diagram showing the light guide 10.

In FIGS. 1, 2, and the like, a cross-sectional shape of the light guide 10 is shown. The light guide 10 extends vertically on a paper plane of FIG. 1 and has almost the same shape in the vertical direction. Hereinafter, the vertical direction will be referred to as extension direction of light guide.

An LED (Light Emitting Diode) is typically used as the light source 5. The LED is mounted on a substrate 8. As in, for example, Japanese Patent Application Laid-open No. 2008-123766, a plurality of LEDs are provided in the extension direction of the light guide 10 for forming linear light in the extension direction of the light guide 10. The light source 5 and the substrate 8 are held by a holder 6 extending in the extension direction of the light guide 10.

The holder 6 is formed such that one end portion thereof is opened and holds the light guide 10 so as to sandwich it.

As shown in FIG. 2, the light guide 10 includes a body light guide portion 13 including an incident end (or incident surface) 13a and a branch light guide portion 15. The branch light guide portion 15 includes a first light guide portion 11 and a second light guide portion 12 that are branched from the body light guide portion 13. The first light guide portion 11 includes an emission end 11a, and the second light guide portion 12 includes an emission end 12a.

The first light guide portion 11 is bent a predetermined angle from the body light guide portion 13 to the irradiation object G side. The position of the light guide 10 with respect to the irradiation object G and the bending angle of the first light guide portion 11 from the body light guide portion 13 are set such that a light flux emitted from the emission end 11a of the first light guide portion 11 (first light flux) directly heads toward the irradiation object G.

The second light guide portion 12 is formed linearly from the incident end 13a to the emission end 12a. A light flux emitted from the emission end 12a (second light flux) heads toward the irradiation object G via the reflection portion 7 and joins the first light flux.

The emission ends 11a and 12a of the first and second light guide portions 11 and 12 each have a light-collecting shape. The light-collecting shape is an outwardly-convex shape, typically a cylindrical shape (R shape). The light-collecting shape may be a sphere or a toroidal shape. By forming the emission ends 11a and 12a in the light-collecting shape as described above, well-shaped accurately-linear light extending in the extension direction of the light guide can be irradiated onto the irradiation object G.

The light guide 10 is typically formed of an acrylic resin, but may instead be formed of glass or other transparent resins.

As shown in FIG. 1, across from the illumination apparatus 100 on the other side of the irradiation object G, a photoelectric conversion device 9 as a photoelectric conversion portion is provided. As the photoelectric conversion device 9, a CCD (Charge Coupled Device) or a CMOS (Complementary Metal-Oxide Semiconductor) device is used, for example.

The irradiation object G is typically paper (script, document, photograph, etc.). Although not shown, the irradiation object G is supported upwardly by a supporting member formed of an optically-transparent material such as glass.

The light flux emitted from the first light guide portion 11 is reflected by the irradiation object G and enters the photoelectric conversion device 9 after passing a space between the light guide 10 and the reflection portion 7.

The light flux emitted from the second light guide portion 12 is reflected by the reflection portion 7, joins the light flux emitted from the first light guide portion 11, is reflected by the irradiation object G, and enters the photoelectric conversion device 9 after passing the space between the light guide 10 and the reflection portion 7.

The illumination apparatus 100 emits linear light in the extension direction of the light guide 10 and irradiates the light onto the irradiation object G. The illumination apparatus 100 and the photoelectric conversion device 9 can integrally move in one direction by a movement mechanism (not shown), and the illumination apparatus 100 irradiates light onto the entire irradiation object G while moving. As a result, the photoelectric conversion device 9 generates an electric signal corresponding to entire image information of the irradiation object G.

As described above, since an image is read while the illumination apparatus 100 is moving, it is better for an irradiation range of the illumination apparatus 100 to be a minimal amount necessary. Since the surfaces of the emission ends 11a and 12a are formed in a light-collecting shape as described above, the irradiation range can be adjusted appropriately although it also depends on a size of the photoelectric conversion device 9 and the like, for example.

Further, the body light guide portion 13 is formed such that a volume thereof (thickness in direction vertical to extension direction of light guide 10) increases from the incident end 13a side to the branch light guide portion 15 side. As a result, directivity of light that passes the body light guide portion 13 can be enhanced, and light fluxes that enter from the light source 5 to be diffused can be efficiently guided to the branch light guide portion 15.

Similar to the body light guide portion 13, the first light guide portion 11 and the second light guide portion 12 are also formed such that volumes thereof increase from the body light guide portion 13 side to the emission ends 11a and 12a side. As a result, directivity of light that is emitted via the first light guide portion 11 and the second light guide portion 12 can be enhanced, and light fluxes that are diffused from the body light guide portion 13 side can be efficiently guided.

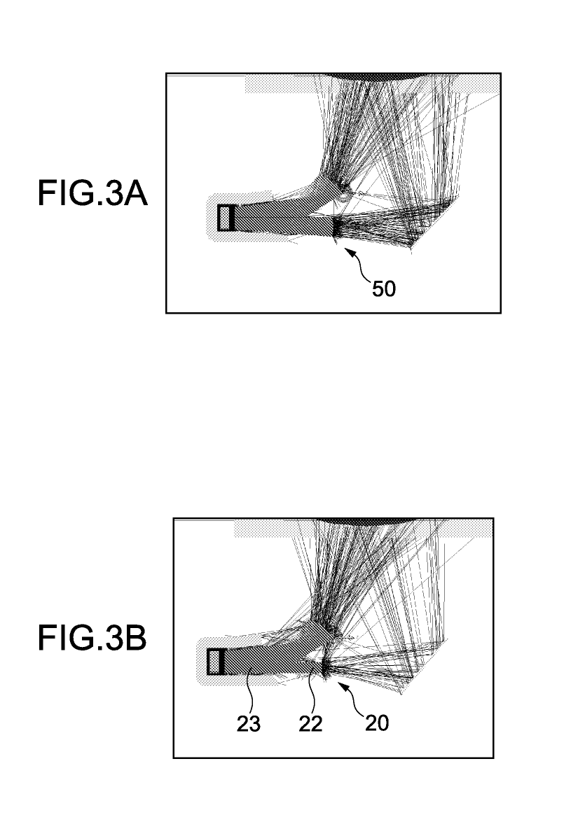

FIG. 3A is a diagram simulating generation of light fluxes by the illumination apparatus 100. It can be seen from the figure that the light fluxes emitted from the branch light guide portion 15 join at the space between the light guide 10 and the irradiation object G to be uniformly irradiated onto the irradiation object G.

FIG. 3B is a diagram simulating generation of light fluxes by an illumination apparatus according to another embodiment of the present disclosure. A light guide 20 of the illumination apparatus of this embodiment is different from the light guide 10 of the first embodiment in that a volume of a second light guide portion 22 is formed to be practically constant from a body light guide portion 23 side to an emission end side.

The simulation conditions of FIGS. 3A and 3B are as follows.

<LED>
Size: 1.6*3.2 mm
Directivity: 120 degrees (50% light amount)

<Light guide>
Material: PMMA (acrylic resin)
Transmittance: 87% (wavelength 380 nm to 760 nm)
Refractive index: 1.4918 (wavelength 587.6 nm)
Critical angle: 42 degrees

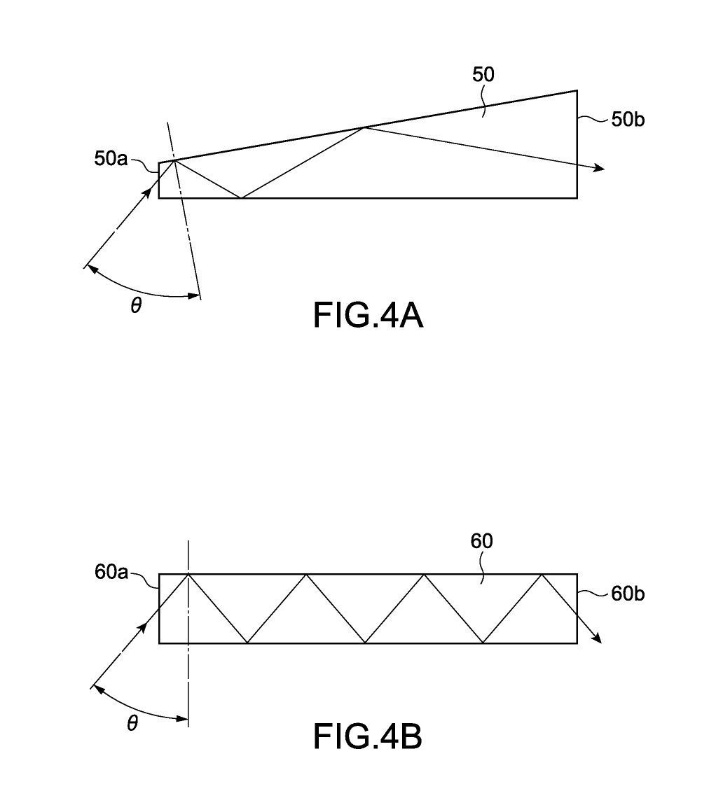

FIG. 4A is a diagram showing one arbitrary light beam in a light guide 50 that is formed such that a volume thereof increases from an incident end 50a side to an emission end 50b side, and FIG. 4B is a diagram showing one light beam in a light guide 60 that is formed such that a volume thereof is practically constant from an incident end 60a side to an emission end 60b side. The incident angles θ are the same in the figures.

In the light guide 50 shown in FIG. 4A, a reflection angle (incident angle with respect to interface) increases every time the light beam is reflected in the light guide 50, and a light beam having higher directivity than the light guide 60 shown in FIG. 4B can be emitted. When the light guide 50 is formed of an acrylic material, a critical angle of the acrylic material is 42 degrees. Therefore, light sharper than that angle is transmitted without being reflected. Accordingly, as the reflection angle increases (becomes blunt), more light can be reflected in the light guide 50.

From the reasons described above, the light guide 10 of this embodiment shown in FIG. 3A can maintain higher directivity and more-efficiently use light from the light source 5 (see FIG. 1) than the light guide 20 shown in FIG. 3B. However, the light guide 20 shown in FIG. 3B is also within an applicable range of the present disclosure.

As described above, in the illumination apparatus 100 of this embodiment, since the first light guide portion 11 and the second light guide portion 12 are branched from the body light guide portion 13 and light fluxes emitted from the first light guide portion 11 and the second light guide portion 12 join, light can be uniformly irradiated onto the irradiation object G.

As a comparative example of the present disclosure, there is a technique that uses two or more light sources for suppressing generation of shadows due to a paste-up script, a pullout script, and the like as described above. However, according to the present disclosure, the same effect as that described above can be obtained with a single light source 5.

Further, in a case where two or more light sources 5 are used and LEDs are used as the light sources 5, unless luminous intensities, chromaticity, and the like of the light sources 5 are set to be almost the same, there is a fear that unevenness of the luminous intensities and chromaticity may be caused. Therefore, in this case, it is necessary for an electronic apparatus to manage the luminous intensities and chromaticity by carrying out, for example, a correction for suppressing such unevenness. However, according to the present disclosure, the luminous intensities and chromaticity do not need to be managed.

### More-Specific Embodiment of Illumination Apparatus According to First Embodiment

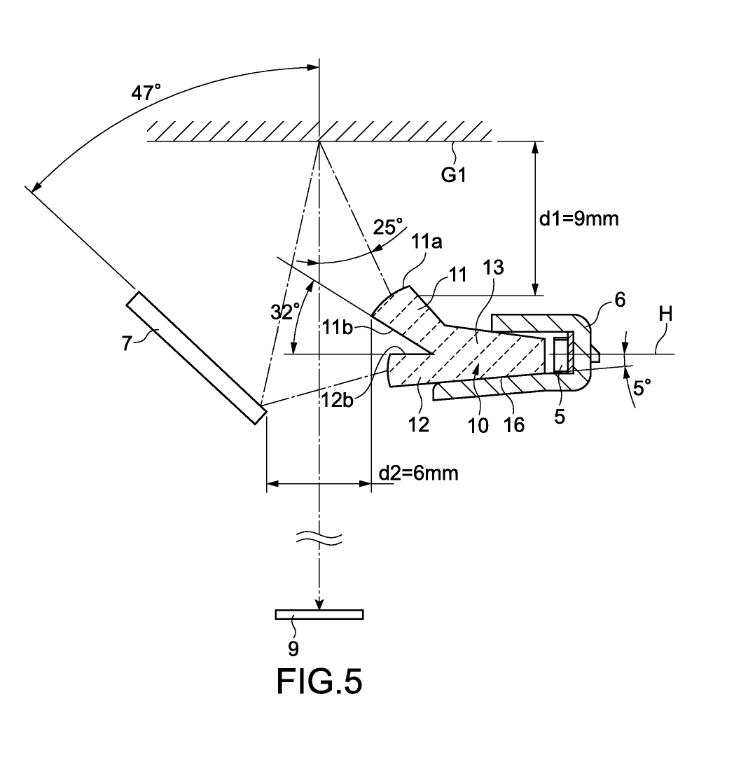

FIG. 5 is a diagram showing a more-specific embodiment of the illumination apparatus 100 according to the first embodiment.

A script surface G1 is practically horizontal.

A distance d1 between the script surface G1 as a surface on which the irradiation object G is mounted and an upper portion of the light guide 10 (substantially center position of surface of emission end 11a of first light guide portion 11) is 9 mm.

A distance d2 between an end portion of the light guide 10 on the reflection portion 7 side and an end portion of the reflection portion 7 on the light guide 10 side is 6 mm.

One surface (lower surface) 16 formed by the body light guide portion 13 and the second light guide portion 12 in the light guide 10 is formed to tilt 5 degrees from the horizontal surface H in a downward direction.

An angle between a surface 11b of the first light guide portion 11 facing the second light guide portion 12 side and a surface 12b of the second light guide portion 12 facing the first light guide portion 11 side is 32 degrees. Moreover, an angle between a reflection surface of the reflection portion 7 and an axis vertical to the horizontal surface H is 47 degrees.

An incident angle of a light flux that has most strong power and is emitted from the emission end 11a with respect to the irradiation surface is 25 degrees.

The embodiment shown in FIG. 5 is a mere example, and the present disclosure is not limited thereto.

### Second Embodiment

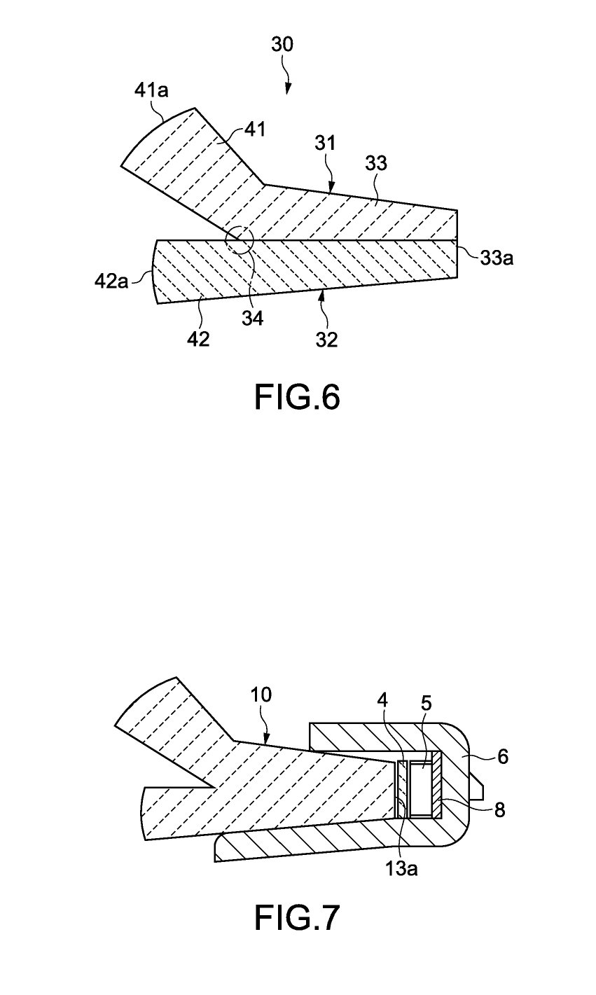

FIG. 6 is a cross-sectional diagram of a light guide according to a second embodiment of the present disclosure. In descriptions below, descriptions on members, functions, and the like that are the same as those included in the illumination apparatus 100 and the light guide 10 according to the embodiment shown in FIG. 1 and the like will be simplified or omitted, and different points will mainly be described.

A light guide 30 is split from an incident end 33a of a body light guide portion 33 to a branching portion 34 of a first light guide portion 41 and second light guide portion 42 branched from the body light guide portion 33. In other words, the light guide 30 includes a first light guide body 31 and a second light guide body 32 that are bonded to form the light guide 30.

The first light guide body 31 is provided on the irradiation object G (see FIG. 1) side and emits a first light flux, and the second light guide body 32 is provided on the other side of the irradiation object G with respect to the first light guide body 31 and emits a second light flux.

Also in this embodiment, the first and second light guide bodies 31 and 32 are formed such that volumes thereof increase from the incident end 33a toward emission ends 41a and 42a.

As described above, by separately providing the first and second light guide bodies 31 and 32 according to irradiation directions of light fluxes, a balance between incident light and emission light in both directions (balance between light amount and light flux direction, etc.) can be easily adjusted when producing the light guide 30. In other words, since outer shapes of the first and second light guide bodies 31 and 32 are simpler than an outer shape in which the first and second light guide bodies 31 and 32 are combined, a balance between incident light and emission light can be easily adjusted by the first and second light guide bodies 31 and 32. As a result, an illumination apparatus conforming to a specification of an electronic apparatus on which the light guide 30 is mounted can be produced.

With the structure as described above, light that has entered from the incident end 33a of the first and second light guide bodies 31 and 32 is continuously reflected by inner portions of the first and second light guide bodies 31 and 32 unless the incident angle falls below the critical angle of the material. Therefore, merely by splitting the light guide 30 from the incident end 33a of the first and second light guide bodies 31 and 32 to the branching portion 34, a shield or the like does not need to be interposed between the interfaces.

### Third Embodiment

FIG. 7 is a cross-sectional diagram showing (a part of) an illumination apparatus according to a third embodiment of the present disclosure.

In the illumination apparatus, a light diffusion member (light diffusion plate or diffusion sheet) 4 is provided between the light source 5 and the incident end 13a of the light guide 10. As the light diffusion member 4, an optically-transparent material whose surface roughness is relatively rough and that has been subjected to, for example, blast processing is used, thus contributing to suppression of irradiation unevenness and uniform light irradiation.

### Other Embodiments

The present disclosure is not limited to the embodiments described above, and various other embodiments may also be realized.

Although a plurality of LEDs are used as the light source 5 in the embodiments above, a fluorescent lamp such as a CCFL (Cold Cathode Fluorescent Lighting (Lamp)) or an EL (Electro-Luminescence) device may be used instead.

Although the branch light guide portion 15 of the light guide 10 of the above embodiment includes two light guide portions (first light guide portion 11 and second light guide portion 12), 3 or more light guide portions may be provided.

The body light guide portion 13, the first light guide portion 11, and the second light guide portion 12 are all formed such that volumes thereof increase from the light incident side toward the emission side. However, at least one of the members does not need to be formed in such a shape. The same holds true for the second and third embodiments.

Although the emission ends are formed in a light-collecting shape in the embodiments above, at least one emission end may take a planar shape such as a concave diffusion shape.

Instead of a scanner or a complex machine alone, a portable electronic apparatus such as a cellular phone and a laptop PC may be used as the electronic apparatus.

It is also possible to combine at least two characteristic portions out of the characteristic portions of the embodiments described above.

The present disclosure may also take the following structure.

(1) A light guide, including:

a body light guide portion including an incident end that light from a light source enters; and

a branch light guide portion including a first light guide portion and a second light guide portion that each include an emission end that a light flux exits and are branched from the body light guide portion, the branch light guide portion being configured to cause, such that a first light flux emitted from the first light guide portion directly heads toward an irradiation object and a second light flux emitted from the second light guide portion heads toward the irradiation object via a reflection portion and joins the first light flux, the first light flux and the second light flux to be emitted from the emission ends.

(2) The light guide according to (1),

in which the body light guide portion is formed such that a volume thereof increases from the incident end side toward the branch light guide portion side.

(3) The light guide according to (1) or (2),

in which at least one of the first light guide portion and the second light guide portion is formed such that a volume thereof increases from the body light guide portion side toward the emission end side.

(4) The light guide according to any one of (1) to (3),

in which the emission end of at least one of the first light guide portion and the second light guide portion is formed in a light-collecting shape.

(5) The light guide according to any one of (1) to (4),

in which the light guide is split from the incident end of the body light guide portion to a branching portion of the first light guide portion and the second light guide portion in the branch light guide portion.

(6) An illumination apparatus, including:

a light source;

a reflection portion; and

a light guide including
a body light guide portion including an incident end that light from the light source enters, and
a branch light guide portion including a first light guide portion and a second light guide portion that each include an emission end that a light flux exits and are branched from the body light guide portion, the branch light guide portion being configured to cause, such that a first light flux emitted from the first light guide portion directly heads toward an irradiation object and a second light flux emitted from the second light guide portion heads toward the irradiation object via the reflection portion and joins the first light flux, the first light flux and the second light flux to be emitted from the emission ends.

(7) The illumination apparatus according to (6), further including

a light diffusion member provided between the light source and the incident end of the light guide.

(8) An electronic apparatus, including:

a light source;

a reflection portion;

a light guide including
a body light guide portion including an incident end that light from the light source enters, and
a branch light guide portion including a first light guide portion and a second light guide portion that each include an emission end that a light flux exits and are branched from the body light guide portion, the branch light guide portion being configured to cause, such that a first light flux emitted from the first light guide portion directly heads toward an irradiation object and a second light flux emitted from the second light guide portion heads toward the irradiation object via the reflection portion and joins the first light flux, the first light flux and the second light flux to be emitted from the emission ends; and

a photoelectric conversion portion configured to receive the light fluxes from the light guide that have been reflected by the irradiation object and convert the light fluxes into an electric signal.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A light guide, comprising:
a body light guide portion including an incident end that light from a light source enters; and
a branch light guide portion including a first light guide portion and a second light guide portion that each include an emission end that a light flux exits and are branched from the body light guide portion, the branch light guide portion being configured to cause, such that a first light flux emitted from the first light guide portion directly heads toward an irradiation object and a second light flux emitted from the second light guide portion heads toward the irradiation object via a reflection portion and joins the first light flux, the first light flux and the second light flux to be emitted from the emission ends.

2. The light guide according to claim 1,
wherein the body light guide portion is formed such that a volume thereof increases from the incident end side toward the branch light guide portion side.

3. The light guide according to claim 1,
wherein at least one of the first light guide portion and the second light guide portion is formed such that a volume thereof increases from the body light guide portion side toward the emission end side.

4. The light guide according to claim 1,
wherein the emission end of at least one of the first light guide portion and the second light guide portion is formed in a light-collecting shape.

5. The light guide according to claim 1,
wherein the light guide is split from the incident end of the body light guide portion to a branching portion of the first light guide portion and the second light guide portion in the branch light guide portion.

6. An illumination apparatus, comprising:
a light source;
a reflection portion; and
a light guide including
a body light guide portion including an incident end that light from the light source enters, and
a branch light guide portion including a first light guide portion and a second light guide portion that each include an emission end that a light flux exits and are branched from the body light guide portion, the branch light guide portion being configured to cause, such that a first light flux emitted from the first light guide portion directly heads toward an irradiation object and a second light flux emitted from the second light guide portion heads toward the irradiation object via the reflection portion and joins the first light flux, the first light flux and the second light flux to be emitted from the emission ends.

7. The illumination apparatus according to claim 6, further comprising
a light diffusion member provided between the light source and the incident end of the light guide.

8. An electronic apparatus, comprising:
a light source;
a reflection portion;
a light guide including
a body light guide portion including an incident end that light from the light source enters, and
a branch light guide portion including a first light guide portion and a second light guide portion that each include an emission end that a light flux exits and are branched from the body light guide portion, the branch light guide portion being configured to cause, such that a first light flux emitted from the first light guide portion directly heads toward an irradiation object and a second light flux emitted from the second light guide portion heads toward the irradiation object via the reflection portion and joins the first light flux, the first light flux and the second light flux to be emitted from the emission ends; and
a photoelectric conversion portion configured to receive the light fluxes from the light guide that have been reflected by the irradiation object and convert the light fluxes into an electric signal.
